(19) United States
(12) Patent Application Publication
(10) Pub. No.: US 2005/0287737 A1
(43) Pub. Date: Dec. 29, 2005

(54) Method for forming storage node electrode of capacitor

(76) Inventors: Ki Seon Park, Kyoungki-do (KR); Jae Sung Roh, Kyoungki-do (KR)

Correspondence Address: LADAS & PARRY LLP, 224 SOUTH MICHIGAN AVENUE, SUITE 1600, CHICAGO, IL, 60604, US

(21) Appl. No.: 11/000,287

(22) Filed: Nov. 30, 2004

(30) Foreign Application Priority Data
Jun. 29, 2004 (KR) 2004-49359

(51) Int. Cl. H01L 21/8242; H01L 21/20

(52) U.S. Cl. 438/239; 438/396; 438/253

(57) ABSTRACT

Disclosed is a method for forming a storage node electrode of a capacitor, capable of preventing wet chemicals from penetrating into an oxide layer. The method includes the steps of preparing a semiconductor substrate, forming a first oxide layer on the semiconductor substrate, forming conductive plugs for filling the first contact holes, sequentially forming an etch stop layer and a second oxide layer on the first oxide layer, forming a first TiN layer on the second oxide layer, performing a plasma treatment process with respect to the first TiN layer, forming a second TiN layer on the amorphous layer, forming a third oxide layer on the second TiN layer, performing an etch-back process with respect to a resultant structure until the second oxide layer is exposed, thereby forming the storage node electrode, and removing remaining second and third oxide layers.

### BACKGROUND OF THE INVENTION

1. Field of the Invention

The present invention relates to a method for fabricating a semiconductor device, and more particularly to a method for forming a storage node electrode of a capacitor, capable of preventing wet chemicals from penetrating into an oxide layer formed at a lower portion of the storage node electrode.

2. Description of the Prior Art

As demands for semiconductor memory devices have been significantly increased, various technologies have been suggested in order to obtain mass-storage capacitors. The capacitor includes a storage node electrode, a plate node electrode and a dielectric layer interposed between the storage node electrode and the plate node electrode. Capacity of the capacitor is directly proportional to a surface area of an electrode and a dielectric constant of the dielectric layer, and inversely proportional to a distance between electrodes, that is, a thickness of the dielectric layer.

Therefore, in order to obtain a mass-storage capacitor, it is necessary to employ a dielectric layer having a great dielectric constant, to enlarge a surface area of an electrode, or reduce a distance between electrodes. However, there is a limitation to reduce the distance between electrodes. That is, there is a limitation to reduce a thickness of the dielectric layer, so studies for the mass-storage capacitor are directed at a method of using the dielectric layer having a great dielectric constant or a method of enlarging the surface area of the electrode.

In order to enlarge the surface area of the electrode, concave type storage node electrodes and cylinder type storage node electrodes have been suggested. Recently, the cylinder type storage node electrode, which enlarges a surface area thereof by utilizing an outer surface of an electrode, is preferably used than the concave type storage node electrode.

FIGS. 1a to 1c are sectional views for explaining a conventional method of forming a storage node electrode of a capacitor. Hereinafter, the conventional method of forming the storage node electrode of the capacitor will be briefly described with reference to FIGS. 1a to 1c.

According to the conventional method of forming the storage node electrode of the capacitor, as shown in FIG. 1a, a semiconductor substrate 10 having a predetermined lower structure (not shown) is prepared first. Then, a first oxide layer 11 having first contact holes 12 for exposing a predetermined portion of the semiconductor substrate 10 is formed on the semiconductor substrate 10. After that, the first contact holes 12 of the first oxide layer 11 are filled with a conductive layer, thereby forming conductive plugs 13.

In addition, an etch stop layer 14 and a second oxide layer 15 having second contact holes 16 for exposing the conductive plug 13 are sequentially deposited on the first oxide layer 11 including the conductive plugs 13.

Then, as shown in FIG. 1b, a TiN layer 17 is formed on the second oxide layer 15 including the second contact holes 16. At this time, the TiN layer 17 is deposited on the second oxide layer 15 through a CVD (chemical vapor deposition) process. Then, a third oxide layer 18 is formed on the TiN layer 17 in such a manner that the second contact holes 16 are filled with the third oxide layer 18.

After that, as shown in FIG. 1c, the third oxide layer 18 and the TiN layer 17 undergo an etch back process until the second oxide layer 15 is exposed, thereby forming a cylinder type storage node electrode 17a. Then, remaining second and third oxide layers are removed by performing a dip-out process. At this time, the dip-out process is carried out with wet chemical, such as BOE solution.

FIG. 2 is a sectional view for explaining a problem of a conventional process, and FIG. 3 is an enlarged sectional view for illustrating an infiltration path of wet chemical in the conventional process.

According to the conventional process, as shown in FIGS. 2 and 3, the TiN layer 17 used for a storage node electrode is grown in a columnar structure due to its grain characteristics, so that gaps can be created in grain boundaries of immature parts of the TiN layer 17. That is, a pinhole or a micro-crack A can be formed in an immature part of the TiN layer 17 as the TiN layer 17 is growing.

Therefore, when the dip-out process is carried out in order to remove remaining second and third oxide layers, wet chemical may penetrate into the first oxide layer 11 formed at a lower portion of the TiN layer 17 through the micro-crack A. Accordingly, the first oxide layer 11 may be etched by means of the wet chemical, so that a bunker type circular defect B is formed in the first oxide layer 11. Such a bunker type circular defect B may reduce a yield rate of semiconductor devices.

### SUMMARY OF THE INVENTION

Accordingly, the present invention has been made to solve the above-mentioned problems occurring in the prior art, and an object of the present invention is to provide a method of forming a storage node electrode of a capacitor, capable of improving a yield rate of semiconductor devices by preventing wet chemical from penetrating into a first oxide layer formed at a lower portion of a TiN layer through pinholes or micro-cracks formed in the TiN layer, in such a manner that the first oxide layer can be prevented from being etched by means of the wet chemical.

In order to accomplish the above object, according to the present invention, there is provided a method for forming a storage node electrode of a capacitor, the method comprising the steps of: preparing a semiconductor substrate having a predetermine bottom structure; forming a first oxide layer on the semiconductor substrate, the first oxide layer having first contact holes for exposing a predetermined portion of the semiconductor substrate; forming conductive plugs for filling the first contact holes; sequentially forming an etch stop layer and a second oxide layer on the first oxide layer including the conductive plugs, the etch stop layer and the second oxide layer having second contact holes for exposing the conductive plugs; forming a first TiN layer on the second oxide layer; performing a plasma treatment process with respect to the first TiN layer, thereby altering a predetermined portion of the first TiN layer into an amorphous layer having a predetermined thickness; forming a second TiN layer on the amorphous layer; forming a third oxide layer on the second TiN layer such that the second contact holes are filled with the third oxide layer; performing an etch-back process with respect to a resultant structure until the second oxide layer is exposed, thereby forming the storage node electrode; and removing remaining second and third oxide layers.

According to the preferred embodiment of the present invention, the first and second TiN layers have a thickness in a range of about 100 to 200 Å. In addition, the first and second TiN layers are formed through a chemical vapor deposition process at a temperature of about 400 to 700° C. while using TiCl₄ and NH₃ as source gases.

The plasma treatment process is carried out while applying 50 to 200 W of power for 10 to 60 seconds by using a parallel plate type RF plasma apparatus. The plasma treatment process is carried out under an Ar gas atmosphere, an atmosphere of Ar and NH₃ gases, or an atmosphere of N₂ and SiH₄ gases.

The amorphous layer has a thickness in a range of about 10 to 50 Å.

### BRIEF DESCRIPTION OF THE DRAWINGS

The above and other objects, features and advantages of the present invention will be more apparent from the following detailed description taken in conjunction with the accompanying drawings, in which:

FIGS. 1a to 1c are sectional views for explaining a conventional method of forming a storage node electrode of a capacitor;

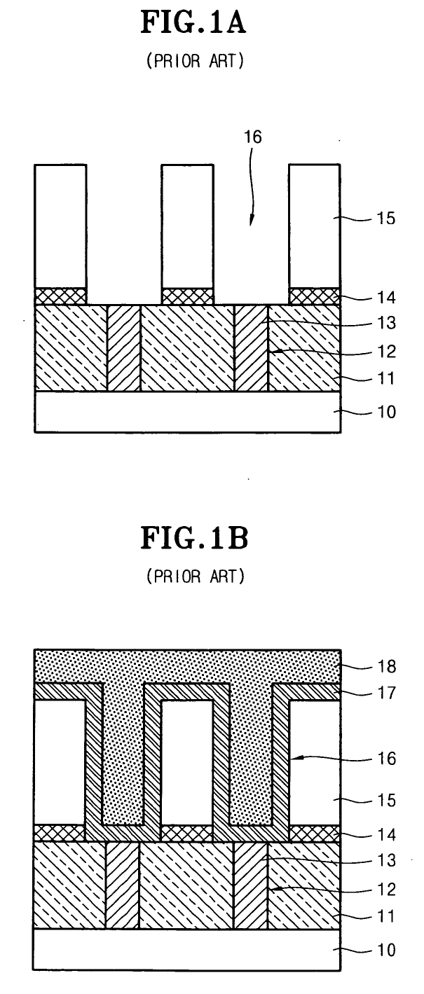

FIG. 2 is a sectional view for explaining a problem of a conventional process;

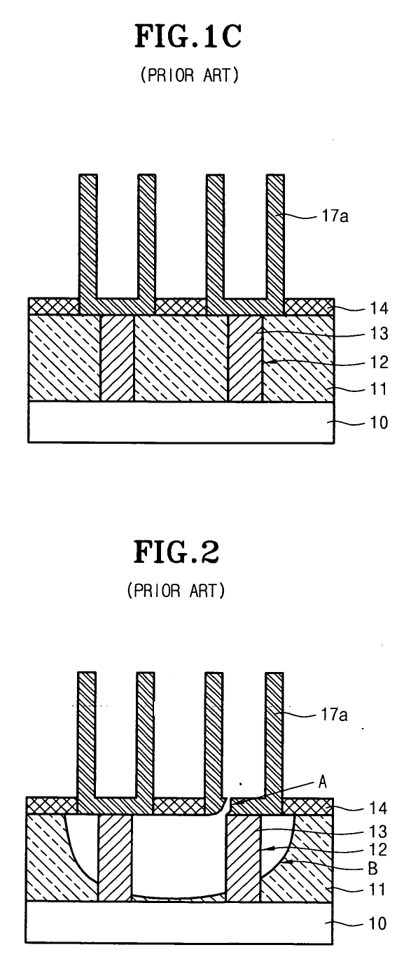

FIG. 3 is an enlarged sectional view for illustrating an infiltration path of wet chemical in the conventional process;

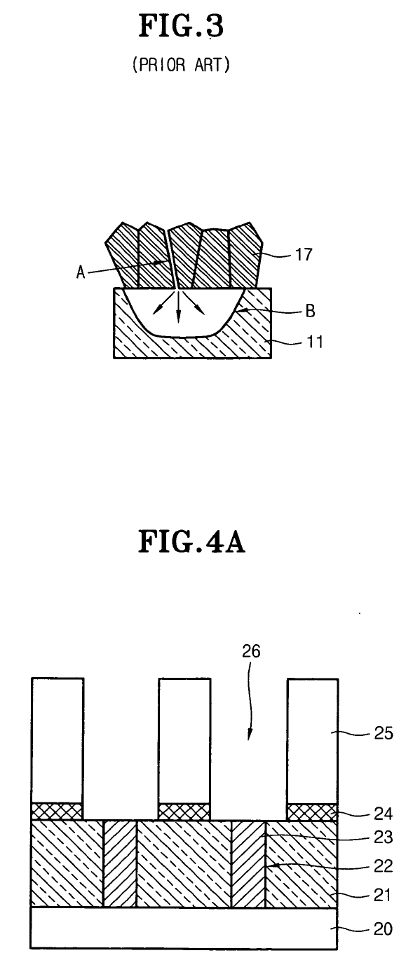

FIGS. 4a to 4c are sectional views for explaining a method of forming a storage node electrode of a capacitor according to one embodiment of the present invention; and

FIG. 5 is an enlarged sectional view illustrating infiltration paths of wet chemical blocked by an amorphous layer.

### DETAILED DESCRIPTION OF THE PREFERRED EMBODIMENTS

Hereinafter, the present invention will be described with reference to accompanying drawings.

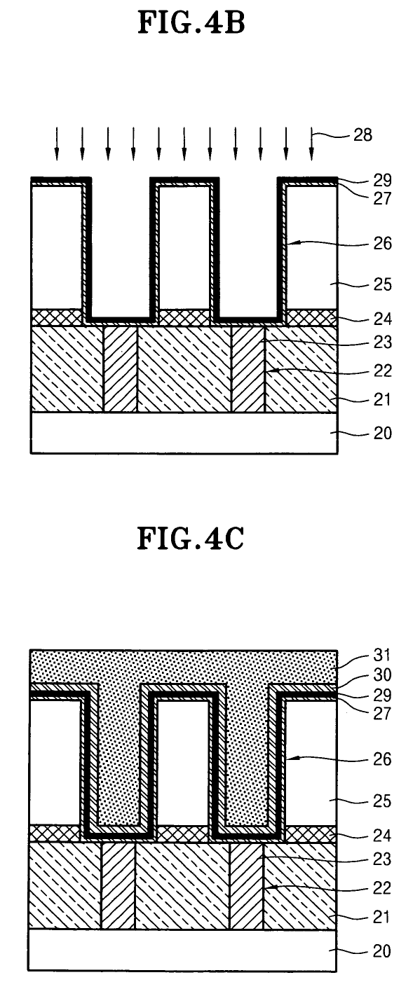

FIGS. 4a to 4d are sectional views for explaining a method of forming a storage node electrode of a capacitor according to one embodiment of the present invention.

According to the method of forming the storage node electrode of the capacitor of the present invention, as shown in FIG. 4a, a semiconductor substrate 20 having a predetermined lower structure (not shown) is prepared first. Then, a first oxide layer 21 having first contact holes 22 for exposing a predetermined portion of the semiconductor substrate 20 is formed on the semiconductor substrate 20.

After that, the first contact holes 22 of the first oxide layer 21 are filled with a conductive layer, thereby forming conductive plugs 23. In addition, an etch stop layer 24 and a second oxide layer 25 having second contact holes 26 for exposing the conductive plug 23 are sequentially deposited on the first oxide layer 21 including the conductive plugs 23.

Then, as shown in FIG. 4b, a first TiN layer 27 is formed on the second oxide layer 25 including the second contact holes 26. Herein, the first TiN layer 27 has a thickness of about 100 to 200 Å. In addition, the first TiN layer 27 is deposited on the second oxide layer 25 through a CVD (chemical vapor deposition) process at a temperature of about 400 to 700° C. while using TiCl₄ and NH₃ as source gases.

Then, as illustrated with reference numeral 28 in FIG. 4b, a plasma treatment process is carried out with respect to the first TiN layer 27, thereby altering a predetermined portion of the first TiN layer 27 into an amorphous layer 29 having a predetermined thickness. Herein, the plasma treatment process is carried out while applying 50 to 200 W of power to the first TiN layer 27 for 10 to 60 seconds by using a parallel plate type RF plasma apparatus. At this time, the plasma treatment process is carried out under an Ar gas atmosphere, an atmosphere of Ar and NH₃ gases, or an atmosphere of N₂ and SiH₄ gases. In addition, the amorphous layer 29 has a thickness of about 10 to 50 Å.

If the plasma treatment process is carried out under the atmosphere of Ar and NH₃ gases, impurities can be removed from the first TiN layer 27, so quality of the first TiN layer 27 can be improved.

In addition, if the plasma treatment process is carried out under the atmosphere of N₂ and SiH₄ gases, a TiSiN layer (not shown) is formed on the surface of the first TiN layer 27. Such a TiSiN layer represents a superior corrosion-proof characteristic against the wet chemical. That is, the TiSiN layer may effectively block the wet chemical penetrating into the first oxide layer 21 during the dip-out process.

Then, as shown in FIG. 4c, a second TiN layer 30 is formed on the amorphous layer 29. At this time, the second TiN layer 30 formed on the amorphous layer 29 has a thickness of about 100 to 200 Å. In addition, the second TiN layer 30 is deposited on the amorphous layer 29 through the CVD process at a temperature of about 400 to 700° C. while using TiCl₄ and NH₃ as source gases.

If the second TiN layer 30 is formed on the amorphous layer 29 after altering the predetermined portion of the first TiN layer 27 into the amorphous layer 29 through the plasma treatment process, a grain direction of the first TiN layer 27 may differ from that of the second TiN layer 30. Therefore, a direction of a pinhole or a micro-crack formed in the first TiN layer 27 may not match with a direction of a pinhole or a micro-crack formed in the second TiN layer 30.

Then, a third oxide layer 31 is formed on the second TiN layer 30 in such a manner that the second contact holes 26 are filled with the third oxide layer 31.

After that, as shown in FIG. 4d, the resultant structure undergoes an etch back process until the second oxide layer is exposed, thereby forming a cylinder type storage node electrode 32. Then, remaining second and third oxide layers are removed by performing a dip-out process. At this time, the dip-out process is carried out with wet chemical, such as BOE solution. In the meantime, in FIG. 4d, reference numeral 27a represents a remaining first TiN layer, reference numeral 29a represents a remaining amorphous layer, and reference numeral 30a represents remaining second TiN layer.

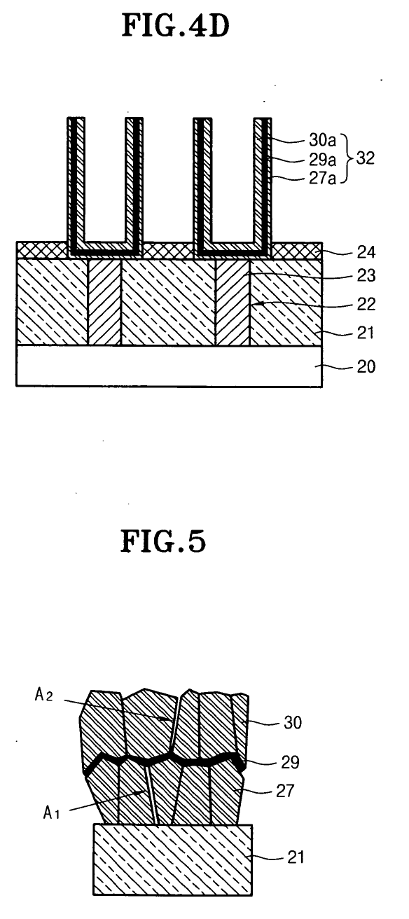

FIG. 5 is an enlarged sectional view illustrating infiltration paths of wet chemical blocked by the amorphous layer.

As shown in FIG. 5, since the upper surface of the first TiN layer 27 is altered into the amorphous layer 29 through the plasma treatment process, the grain direction of the first TiN layer 27 may differ from the grain direction of the second TiN layer 30. Accordingly, even if pinholes or micro-cracks A₁ and A₂ are formed in the immature portions of the first and second TiN layers 27 and 30, directions of the pinholes or micro-cracks A₁ and A₂ may offset from each other. Thus, the wet chemical is prevented from penetrating into the first oxide layer 21 formed at the lower portion of the first TiN layer 27 through the pinholes or micro-cracks A₁ and A₂ during the dip-out process. Therefore, it is possible to prevent the first oxide layer 21 from be etched by means of the wet chemical.

As described above, when forming the storage node electrode according to the present invention, the first TiN layer is primarily formed and the plasma treatment process is carried out with respect to the first TiN layer in such a manner that a predetermined portion of the first TiN layer is altered into the amorphous layer. After that, the second TiN layer is formed on the amorphous layer, so that the grain direction of the first TiN layer may differ from the grain direction of the second TiN layer.

Accordingly, the direction of the pinholes or micro-cracks formed in the first TiN layer may offset from the direction of the pinholes or micro-cracks formed in the second TiN layer, so the wet chemical can be prevented from penetrating into the first oxide layer formed at the lower portion of the first TiN layer through the pinholes or micro-cracks during the dip-out process.

Therefore, the present invention can prevent the oxide layer formed at the lower portion of the storage node electrode from being etched by means of the wet chemical, thereby improving the yield rate of semiconductor devices.

Although a preferred embodiment of the present invention has been described for illustrative purposes, those skilled in the art will appreciate that various modifications, additions and substitutions are possible, without departing from the scope and spirit of the invention as disclosed in the accompanying claims.

1. A method for forming a storage node electrode of a capacitor, the method comprising the steps of:
i) preparing a semiconductor substrate having a predetermine bottom structure;
ii) forming a first oxide layer on the semiconductor substrate, the first oxide layer having first contact holes for exposing a predetermined portion of the semiconductor substrate;
iii) forming conductive plugs for filling the first contact holes;
iv) sequentially forming an etch stop layer and a second oxide layer on the first oxide layer including the conductive plugs, the etch stop layer and the second oxide layer having second contact holes for exposing the conductive plugs;
v) forming a first TiN layer on the second oxide layer;
vi) performing a plasma treatment process with respect to the first TiN layer, thereby altering a predetermined portion of the first TiN layer into an amorphous layer having a predetermined thickness;
vii) forming a second TiN layer on the amorphous layer;
viii) forming a third oxide layer on the second TiN layer such that the second contact holes are filled with the third oxide layer;
ix) performing an etch-back process with respect to a resultant structure until the second oxide layer is exposed, thereby forming the storage node electrode; and
x) removing remaining second and third oxide layers.

2. The method as claimed in claim 1, wherein the first and second TiN layers have a thickness in a range of about 100 to 200 Å.

3. The method as claimed in claim 1, wherein the first and second TiN layers are formed through a chemical vapor deposition process at a temperature of about 400 to 700° C. while using TiCl₄ and NH₃ as source gases.

4. The method as claimed in claim 1, wherein the plasma treatment process is carried out while applying 50 to 200 W of power for 10 to 60 seconds by using a parallel plate type RF plasma apparatus.

5. The method as claimed in claim 1, wherein the plasma treatment process is carried out under an Ar gas atmosphere.

6. The method as claimed in claim 1, wherein the plasma treatment process is carried out under an atmosphere of Ar and NH₃ gases.

7. The method as claimed in claim 1, wherein the plasma treatment process is carried out under an atmosphere of N₂ and SiH₄ gases.

8. The method as claimed in claim 1, wherein the amorphous layer has a thickness in a range of about 10 to 50 Å.
